(19) United States
(12) Patent Application Publication
(10) Pub. No.: US 2023/0101149 A1
(43) Pub. Date: Mar. 30, 2023

(54) SEMICONDUCTOR PACKAGE

(71) Applicant: Samsung Electronics Co., Ltd., Suwon-si (KR)

(72) Inventors: TAEWON YOO, Seoul (KR); JONGYOUN KIM, Seoul (KR); KYOUNG LIM SUK, Suwon-si (KR); SEOKHYUN LEE, Hwaseong-si (KR); HYEONJEONG HWANG, Cheonan-si (KR)

(21) Appl. No.: 17/843,967

(22) Filed: Jun. 18, 2022

(30) Foreign Application Priority Data
Sep. 24, 2021 (KR) 10-2021-0126382

(51) Int. Cl. H01L 23/367; H01L 25/10; H01L 23/31; H01L 25/18

(52) U.S. Cl. CPC H01L 23/367; H01L 23/3677; H01L 25/105; H01L 23/3135; H01L 25/18; H01L 23/3128; H01L 2225/1035; H01L 2225/1094; H01L 24/16

(57) ABSTRACT

A semiconductor package is disclosed. The semiconductor package may include a first redistribution substrate including a first insulating layer and a first redistribution pattern, a lower semiconductor chip mounted on the first redistribution substrate, a conductive structure disposed on the first redistribution substrate and horizontally spaced apart from the lower semiconductor chip, a first mold layer interposed between the first redistribution substrate and the second redistribution substrate to cover the lower semiconductor chip and the conductive structure, a second redistribution substrate on the first redistribution substrate, the second redistribution substrate including a second insulating layer and a second redistribution pattern, a first heat-dissipation pattern interposed between the lower semiconductor chip and the second insulating layer, and a heat-dissipation pad on the conductive structure. A top surface of the first heat-dissipation pattern may be located at a level higher than a top surface of the conductive structure.

### CROSS-REFERENCE TO RELATED APPLICATIONS

This U.S. non-provisional patent application claims priority under 35 U.S.C. § 119 to Korean Patent Application No. 10-2021-0126382, filed on Sep. 24, 2021, in the Korean Intellectual Property Office, the entire contents of which are hereby incorporated by reference.

### BACKGROUND OF THE INVENTION

The present disclosure relates to a semiconductor package, and in particular, to a semiconductor package including a redistribution substrate.

A semiconductor package is configured to easily use a semiconductor chip as a part of an electronic product. In general, the semiconductor package includes a printed circuit board (PCB) and a semiconductor chip, which is mounted on the PCB and is electrically connected to the PCB by bonding wires or bumps. With the recent development of the electronics industry, a semiconductor package technology is developing in various ways with the goal of miniaturization, weight reduction, and manufacturing cost reduction. In addition, as the use of this technology is expanded to various fields such as mass storage devices, various types of semiconductor packages are emerging. In particular, as the semiconductor device consumes more electric power for fast speed and large capacity, the importance of the thermal characteristics of the semiconductor package is increasing.

### SUMMARY

An embodiment of the inventive concept provides a semiconductor package with an improved heat-dissipation property.

According to an embodiment of the inventive concept, a semiconductor package may include a first redistribution substrate including a first insulating layer and a first redistribution pattern, a lower semiconductor chip mounted on the first redistribution substrate, a conductive structure disposed on the first redistribution substrate and horizontally spaced apart from the lower semiconductor chip, a first mold layer interposed between the first redistribution substrate and the second redistribution substrate to cover the lower semiconductor chip and the conductive structure, a second redistribution substrate on the first redistribution substrate, the second redistribution substrate including a second insulating layer and a second redistribution pattern, a first heat-dissipation pattern interposed between the lower semiconductor chip and the second insulating layer, and a heat-dissipation pad on the conductive structure. A top surface of the first heat-dissipation pattern may be located at a level higher than a top surface of the conductive structure.

According to an embodiment of the inventive concept, a semiconductor package may include a first redistribution substrate, a lower semiconductor chip mounted on the first redistribution substrate, a conductive structure disposed on the first redistribution substrate and horizontally spaced apart from the lower semiconductor chip, a second redistribution substrate on the first redistribution substrate, a heat-dissipation pattern on the lower semiconductor chip, a protection pattern interposed between the lower semiconductor chip and the heat-dissipation pattern and provided to expose a top surface of the heat-dissipation pattern, and a heat-dissipation pad on the conductive structure.

According to an embodiment of the inventive concept, a semiconductor package may include a first redistribution substrate including a first insulating layer and a first redistribution pattern, a first lower semiconductor chip mounted on the first redistribution substrate, a conductive structure disposed on the first redistribution substrate and horizontally spaced apart from the first lower semiconductor chip, a first mold layer provided on the first redistribution substrate to cover the first lower semiconductor chip and the conductive structure, a second redistribution substrate on the first redistribution substrate, the second redistribution substrate including a second insulating layer and a second redistribution pattern, a first heat-dissipation pattern interposed between the first lower semiconductor chip and the second insulating layer, a first protection pattern interposed between the first lower semiconductor chip and the first heat-dissipation pattern and provided to expose a top surface of the first heat-dissipation pattern, a heat-dissipation pad on the conductive structure, a pad protection pattern interposed between the conductive structure and the heat-dissipation pad, and a first upper semiconductor chip mounted on the second redistribution substrate.

### BRIEF DESCRIPTION OF THE DRAWINGS

FIG. 1 is a plan view illustrating a semiconductor package, according to an example embodiment of the inventive concept.

FIG. 2 is a sectional view, which is taken along a line I-I′ of FIG. 1, to illustrate a semiconductor package, according to an example embodiment of the inventive concept.

FIG. 3A is an enlarged sectional view illustrating a portion A of FIG. 2.

FIG. 3B is an enlarged sectional view illustrating the portion A of FIG. 2.

FIG. 4 is a plan view illustrating a semiconductor package, according to an example embodiment of the inventive concept.

FIG. 5 is a sectional view, which is taken along a line I-I′ of FIG. 4, to illustrate a semiconductor package, according to an example embodiment of the inventive concept.

FIG. 6A is an enlarged sectional view illustrating a portion B of FIG. 5.

FIG. 6B is an enlarged sectional view illustrating the portion B of FIG. 5.

FIG. 7 is a plan view illustrating a semiconductor package, according to an example embodiment of the inventive concept.

FIG. 8 is a sectional view, which is taken along a line I-I′ of FIG. 7, to illustrate a semiconductor package, according to an example embodiment of the inventive concept.

FIG. 9 is a sectional view illustrating a semiconductor package, according to an example embodiment of the inventive concept.

FIG. 10 is a sectional view illustrating a semiconductor package, according to an example embodiment of the inventive concept.

FIGS. 11 to 18 are sectional views illustrating a method of fabricating a semiconductor package, according to an example embodiment of the inventive concept.

### DETAILED DESCRIPTION

Example embodiments of the inventive concepts will now be described more fully with reference to the accompanying drawings, in which example embodiments are shown. Like numerals refer to like elements throughout. Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

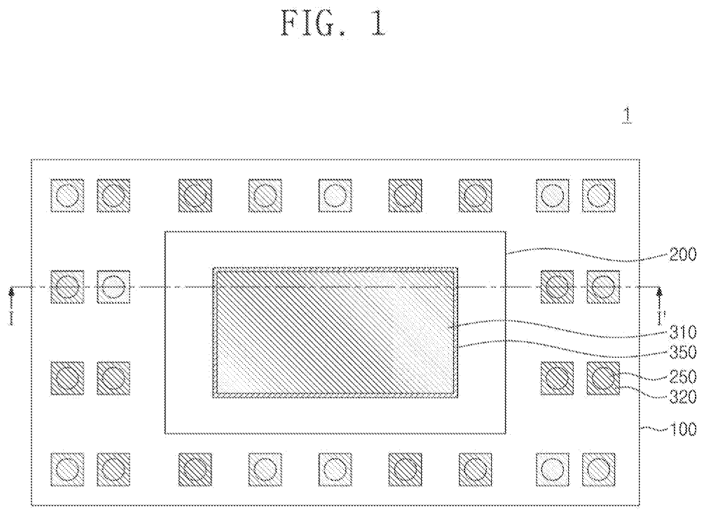

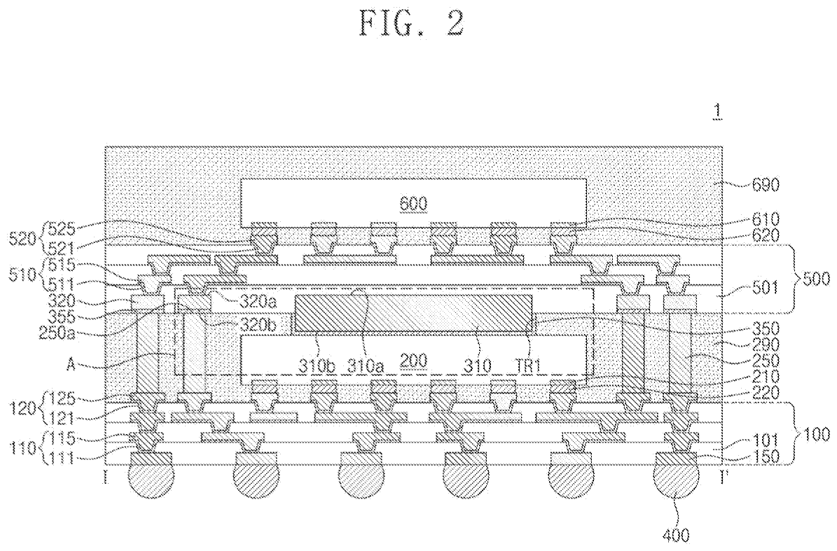

FIG. 1 is a plan view illustrating a semiconductor package according to an example embodiment of the inventive concept. FIG. 2 is a sectional view, which is taken along a line I-I′ of FIG. 1 to illustrate a semiconductor package according to an example embodiment of the inventive concept.

Referring to FIGS. 1 and 2, a semiconductor package 1 may include a first redistribution substrate 100, a lower semiconductor chip 200, an upper semiconductor chip 600, a first heat-dissipation pattern 310, a heat-dissipation pad 320, and a second redistribution substrate 500.

The first redistribution substrate 100 may be provided. The first redistribution substrate 100 may include a first insulating layer 101, a first redistribution pattern 110, a first pad structure 120, and an under-bump pattern 150. In an embodiment, a plurality of the first insulating layers 101 may be provided in the stacked form. However, the stacked number of the first insulating layers 101 is not limited to that in the illustrated example and may be variously changed. In an embodiment, the first insulating layers 101 may be formed of or may include the same material, and in this case, there may be no observable interface between the first insulating layers 101. In another embodiment, there may be an observable interface between the first insulating layers 101. The first insulating layers 101 may be formed of or may include an organic material (e.g., photosensitive polymer). The photosensitive polymer may include at least one of, for example, photosensitive polyimide, polybenzoxazole, phenol-based polymer, and benzocyclobutene-based polymer. As an example, the first insulating layers 101 may be formed of or may include a photo imageable dielectric (PID).

The under-bump pattern 150 may be provided in the first insulating layer 101. In an embodiment, a plurality of the under-bump patterns 150 may be provided. The under-bump patterns 150 may be disposed adjacent to a bottom surface of the first redistribution substrate 100. The first insulating layer 101 may cover the under-bump patterns 150. The first insulating layer 101 may be provided to expose bottom surfaces of the under-bump patterns 150. For example, bottom surfaces of the first insulating layer 101 and the under-bump patterns 150 may be coplanar with one another. The under-bump patterns 150 may be spaced apart from each other in a horizontal direction (e.g., a direction parallel to a top surface of the first redistribution substrate 100). The under-bump patterns 150 may serve as pads of outer terminals 400, which will be described below. The under-bump pattern 150 may be formed of or may include at least one of conductive metal materials (e.g., copper (Cu)).

The first redistribution pattern 110 may be provided in the first redistribution substrate 100. The first redistribution pattern 110 may be disposed on the under-bump patterns 150. In an embodiment, a plurality of the first redistribution patterns 110 may be provided. The first redistribution patterns 110 may be stacked. As an example, the lowermost ones of the first redistribution patterns 110 may be in contact with the under-bump patterns 150. However, the stacked number of the first redistribution patterns 110 is not limited to that in the illustrated example and may be variously changed. The first redistribution patterns 110 may be electrically connected to at least one of the under-bump patterns 150. Each of the first redistribution patterns 110 may include a first seed pattern 111 and a first conductive pattern 115. In the present specification, the expression “two elements are electrically connected/coupled to each other” may mean that the elements are directly connected/coupled to each other or are indirectly connected/coupled to each other through another conductive element. As used herein, the term “contact” refers to a direct connection (i.e., touching) unless the context indicates otherwise.

The first conductive pattern 115 may be disposed on the first seed pattern 111. The first conductive pattern 115 may include a first via portion and a first wire portion on the first via portion. The first wire portion and the first via portion may be connected to each other without an interface therebetween. For example, the first wire portion and the first via portion may be in material continuity with each other. As used herein, the term “material continuity” may refer to structures, patterns, and/or layers that are formed at the same time and of the same material, without a break in the continuity of the material of which they are formed. The first wire portion may have a long axis that is extended in a horizontal direction (e.g., parallel to the top surface of the first redistribution substrate 100). For example, a width of the first wire portion may be larger than a width of the first via portion. The first via portion may have a shape protruding toward the bottom surface of the first redistribution substrate 100. For example, a width of the first via portion may narrow as the first via portion extends toward the bottom surface of the first redistribution substrate 100. The first via portion may be provided in a corresponding one of the first insulating layers 101, and the first wire portion may be extended to a region on a top surface of the corresponding one of the first insulating layers 101. The first conductive pattern 115 may be formed of or may include at least one of conductive metal materials (e.g., copper (Cu)). In the present specification, a width of an element may mean a length of the element measured in a direction parallel to the top surface of the first redistribution substrate 100.

The first seed pattern 111 may be provided on a bottom surface of the first conductive pattern 115. The first seed pattern 111 may be interposed between the first conductive pattern 115 and the first insulating layer 101. The first seed pattern 111 may be formed of or may include at least one of conductive metal materials (e.g., copper (Cu), titanium (Ti), and/or alloys thereof).

The first pad structure 120 may be provided on the uppermost one of the first redistribution patterns 110. In an embodiment, a plurality of the first pad structures 120 may be provided to be horizontally spaced apart from each other. The first pad structures 120 may have top surfaces that are exposed to the outside of the first insulating layer 101. The first pad structures 120 may be electrically connected to at least one of the first redistribution patterns 110. Each of the first pad structures 120 may include a first pad seed pattern 121 and a first pad conductive pattern 125.

The first pad conductive pattern 125 may be disposed on the first pad seed pattern 121. The first pad conductive pattern 125 may include a first pad via portion and a first pad wire portion on the first pad via portion. The first pad wire portion and the first pad via portion may be connected to each other without an interface therebetween. For example, the first pad wire portion and the first pad via portion may be in material continuity with one another. The first pad wire portion may have a long axis that is extended in a horizontal direction (e.g., parallel to the top surface of the first redistribution substrate 100). For example, a width of the first pad wire portion may be larger than a width of the first pad via portion. The first pad via portion may have a shape protruding toward the bottom surface of the first redistribution substrate 100. The first pad via portion may be provided in the uppermost one of the first insulating layers 101, and the first pad wire portion may be extended to a region on a top surface of the uppermost one of the first insulating layers 101. The first pad conductive pattern 125 may be formed of or may include at least one of conductive metal materials (e.g., copper (Cu)).

The first pad seed pattern 121 may be provided on a bottom surface of the first pad conductive pattern 125. The first pad seed pattern 121 may be interposed between the first pad conductive pattern 125 and the first insulating layer 101. The first pad seed pattern 121 may be interposed between a bottom surface of the first pad wire portion and the first insulating layer 101, between a side surface of the first pad via portion and the first insulating layer 101, and between a bottom surface of the first pad via portion and a corresponding one of the first redistribution patterns 110. The first pad seed pattern 121 may be in direct contact with the first wire portion of the first redistribution pattern 110 that is adjacent to the bottom surface thereof. The first pad seed pattern 121 may be formed of or may include at least one of conductive metal materials (e.g., copper (Cu), titanium (Ti), and/or alloys thereof).

An outer terminal 400 may be provided on the bottom surface of the first redistribution substrate 100. In an embodiment, a plurality of the outer terminals 400 may be provided to be horizontally spaced apart from each other. The outer terminals 400 may be disposed on the bottom surfaces of the under-bump patterns 150. The outer terminal 400 may be provided in the form of at least one of solder balls, solder pillars, and solder bumps. The outer terminal 400 may include a conductive metal material. For example, the outer terminal 400 may be formed of or may include at least one of tin (Sn), lead (Pb), nickel (Ni), gold (Au), silver (Ag), copper (Cu), aluminum (Al), or bismuth (Bi). The outer terminal 400 may be coupled to an external device (not shown).

The lower semiconductor chip 200 may be mounted on the top surface of the first redistribution substrate 100. In an embodiment, the lower semiconductor chip 200 may be a memory chip, a logic chip, or a sensing chip, but the inventive concept is not limited to this example. The memory chip may be one of, for example, DRAM, SRAM, MRAM, and FLASH memory chips. The lower semiconductor chip 200 may include first chip pads 210 provided near a bottom surface thereof. The first chip pads 210 may be electrically connected to integrated circuits of the lower semiconductor chip 200 through interconnection lines in the lower semiconductor chip 200. The first chip pads 210 may be formed of or may include at least one of conductive metal materials (e.g., copper (Cu)).

A first connection terminal 220 may be provided on the first redistribution substrate 100. The first connection terminal 220 may be disposed on the first pad structure 120. In an embodiment, a plurality of the first connection terminals 220 may be provided to be horizontally spaced apart from each other. The first connection terminals 220 may be interposed between the first redistribution substrate 100 and the lower semiconductor chip 200. The first connection terminals 220 may be interposed between and electrically connected to the first pad structures 120 and the first chip pads 210. The lower semiconductor chip 200 may be electrically connected to the first redistribution substrate 100 through the first connection terminals 220. Each of the first connection terminals 220 may be in contact with a top surface of a corresponding one of the first pad structures 120 and a bottom surface of a corresponding one of the first chip pads 210. The first connection terminals 220 may be provided in the form of at least one of solder balls, solder pillars, and solder bumps. The first connection terminals 220 may include a conductive metal material. The first connection terminals 220 may be formed of or may include at least one of, for example, tin (Sn), lead (Pb), nickel (Ni), gold (Au), silver (Ag), copper (Cu), aluminum (Al), or bismuth (Bi).

A conductive structure 250 may be disposed on the top surface of the first redistribution substrate 100 and may be electrically connected to a corresponding one of the first pad structures 120. In an embodiment, a plurality of the conductive structures 250 may be provided to be horizontally spaced apart from each other. The conductive structures 250 may be horizontally spaced apart from the lower semiconductor chip 200. The conductive structures 250 may be disposed on an edge region of the first redistribution substrate 100, when viewed in a plan view, and may surround the lower semiconductor chip 200. The conductive structures 250 may be electrically connected to at least one of the first redistribution patterns 110. In example embodiments, each of the conductive structures 250 may contact a top surface of a corresponding one of the first redistribution patterns 110. In an embodiment, the conductive structure 250 may be a metal pillar. For example, the conductive structure 250 may be formed of or may include copper (Cu).

A first mold layer 290 may be provided on the first redistribution substrate 100. The first mold layer 290 may be interposed between the first redistribution substrate 100 and the second redistribution substrate 500. The first mold layer 290 may cover the top surface of the first redistribution substrate 100 and the lower semiconductor chip 200. The first mold layer 290 may cover side surfaces and a portion of a top surface of the lower semiconductor chip 200. In example embodiments, a top surface of the first mold layer 290 may be at a higher vertical level than the top surface of the lower semiconductor chip 200. The first mold layer 290 may cover the conductive structures 250. The first mold layer 290 may be interposed between the first connection terminals 220 to cover the first connection terminals 220. The first mold layer 290 may be provided to have a first trench TR1 exposing a portion of the top surface of the lower semiconductor chip 200. The first mold layer 290 may be formed of or may include at least one of, for example, insulating polymers (e.g., epoxy molding compounds).

The second redistribution substrate 500 may be provided on the first redistribution substrate 100. The second redistribution substrate 500 may be disposed on the first mold layer 290. The second redistribution substrate 500 may include a second insulating layer 501, a second redistribution pattern 510, and a second pad structure 520. In an embodiment, a plurality of the second insulating layers 501 may be provided in the stacked form. However, the stacked number of the second insulating layers 501 is not limited to that in the illustrated example and may be variously changed. In an embodiment, the second insulating layers 501 may be formed of or may include the same material, and there may be no observable interface between the second insulating layers 501. In another embodiment, there may be an observable interface between the second insulating layers 501. The second insulating layers 501 may be formed of or may include an organic material (e.g., a photosensitive polymer). The photosensitive polymer may include at least one of, for example, photosensitive polyimide, polybenzoxazole, phenol-based polymer, and benzocyclobutene-based polymer. As an example, the second insulating layers 501 may be formed of or may include a photo imageable dielectric (PID).

The first heat-dissipation pattern 310 may be provided on the lower semiconductor chip 200. The first heat-dissipation pattern 310 may be interposed between the lower semiconductor chip 200 and the second insulating layer 501. The first heat-dissipation pattern 310 may be disposed in the first trench TR1. For example, a bottom surface of the first heat-dissipation pattern 310 may be at a lower vertical level than a top surface of the first mold layer 290, and a top surface of the first heat-dissipation pattern 310 may be at a higher vertical level than a top surface of the first mold layer 290. The first heat-dissipation pattern 310 may cover at least a portion of the lower semiconductor chip 200. The first heat-dissipation pattern 310 may be disposed on a bottom surface of the second redistribution pattern 510. The first heat-dissipation pattern 310 may be disposed at a level different from the second redistribution pattern 510. For example, a bottom surface of the first heat-dissipation pattern 310 may be at a lower vertical level than a bottom surface of the second redistribution pattern 510, and a top surface of the first heat-dissipation pattern 310 may be at a higher vertical level than the bottom surface of the second redistribution pattern 510. The first heat-dissipation pattern 310 and a second wire portion of the second redistribution pattern 510, which will be described below, may be disposed in different ones of the second insulating layers 501. The first heat-dissipation pattern 310 may be disposed on a center region of the first redistribution substrate 100, when viewed in a plan view. The first heat-dissipation pattern 310 may have a rectangular shape, when viewed in a plan view. However, the inventive concept is not limited to this example, and unlike the illustrated structure, the first heat-dissipation pattern 310 may have a circular or polygonal shape, when viewed in a plan view. In the present specification, a level of an element may mean a vertical height of the element measured from the top surface of the first redistribution substrate 100. The first heat-dissipation pattern 310 may be formed of or may include at least one of conductive metal materials (e.g., copper (Cu)).

In an embodiment, a width of the first heat-dissipation pattern 310 may be smaller than a width of the lower semiconductor chip 200. In another embodiment, unlike the illustrated structure, the first heat-dissipation pattern 310 may be provided to cover the entire top surface of the lower semiconductor chip 200. For example, in some embodiments, the width of the first heat-dissipation pattern 310 may be substantially equal to or larger than the width of the lower semiconductor chip 200.

A first protection pattern 350 may be provided on a bottom surface 310b of the first heat-dissipation pattern 310. The first protection pattern 350 may cover a lower portion of the first heat-dissipation pattern 310. The first protection pattern 350 may be provided to cover the bottom surface 310b and lower side surfaces of the first heat-dissipation pattern 310. The first protection pattern 350 may contact the bottom surface 310b and lower side surfaces of the first heat-dissipation pattern 310. The first protection pattern 350 may be interposed between the lower side surface of the first heat-dissipation pattern 310 and the first mold layer 290 and between the bottom surface 310b of the first heat-dissipation pattern 310 and the lower semiconductor chip 200. The first protection pattern 350 may be provided to expose a top surface 310a and upper side surfaces of the first heat-dissipation pattern 310. The first protection pattern 350 may be formed of or may include a material that is different from the first heat-dissipation pattern 310. The first protection pattern 350 may be formed of or may include at least one of conductive metal materials (e.g., titanium (Ti)).

The heat-dissipation pad 320 may be provided on the first redistribution substrate 100. The heat-dissipation pad 320 may be disposed on the first mold layer 290. In an embodiment, a plurality of the heat-dissipation pads 320 may be disposed to be horizontally spaced apart from each other. The heat-dissipation pads 320 may be disposed in the second insulating layer 501. The heat-dissipation pads 320 may be interposed between the conductive structure 250 and the second insulating layer 501. The heat-dissipation pads 320 may be provided to cover corresponding ones of the conductive structures 250. The heat-dissipation pads 320 may be spaced apart from the first heat-dissipation pattern 310. The heat-dissipation pads 320 may be disposed on the bottom surface of the second redistribution pattern 510. The heat-dissipation pads 320 may be disposed at a level different from the second redistribution pattern 510. For example, bottom surfaces of the heat-dissipation pads 320 may be at a higher vertical level than a bottom surface of the second redistribution pattern 510. The heat-dissipation pads 320 and the second wire portion of the second redistribution pattern 510 may be disposed in different ones of the second insulating layers 501. The heat-dissipation pads 320 may be disposed on the edge region of the first redistribution substrate 100, when viewed in a plan view, and may surround the lower semiconductor chip 200. The heat-dissipation pad 320 may have a rectangular shape, when viewed in a plan view. However, the inventive concept is not limited to this example, and unlike the illustrated structure, the heat-dissipation pad 320 may have a circular or polygonal shape, when viewed in a plan view. The heat-dissipation pad 320 may be formed of or may include the same material as the first heat-dissipation pattern 310. The heat-dissipation pad 320 may be formed of or may include at least one of conductive metal materials (e.g., copper (Cu)).

A pad protection pattern 355 may be provided on a bottom surface 320b of each of the heat-dissipation pads 320. The pad protection patterns 355 may be disposed on the first mold layer 290. Each of the pad protection patterns 355 may cover the bottom surface 320b of the heat-dissipation pad 320 and a top surface 250a of the conductive structure 250. For example, each of the pad protection patterns 355 may contact the bottom surface 320b of a corresponding one of the heat-dissipation pads 320 and a top surface 250a of a corresponding one of the conductive structures 250. Each of the pad protection patterns 355 may be interposed between the heat-dissipation pad 320 and the conductive structure 250. Each of the pad protection patterns 355 may be interposed between the bottom surface 320b of the heat-dissipation pad 320 and the first mold layer 290 and between the bottom surface 320b of the heat-dissipation pad 320 and the conductive structure 250. Each of the pad protection patterns 355 may be provided to expose a top surface 320a and side surfaces of the heat-dissipation pad 320. The pad protection pattern 355 may be formed of or may include a material that is different from the heat-dissipation pad 320. The pad protection pattern 355 may be formed of or may include the same material as the first protection pattern 350. The pad protection pattern 355 may be formed of or may include at least one of conductive metal materials (e.g., titanium (Ti)).

The top surface 310a of the first heat-dissipation pattern 310 and the top surface 320a of the heat-dissipation pad 320 may be located at a level higher than the top surface 250a of the conductive structure 250. The top surface 310a of the first heat-dissipation pattern 310 may be located at substantially the same level as the top surface 320a of the heat-dissipation pad 320. The bottom surface 310b of the first heat-dissipation pattern 310 may be located at a level lower than the bottom surface 320b of the heat-dissipation pad 320. A thickness of the first heat-dissipation pattern 310 may be larger than a thickness of the heat-dissipation pad 320. In the present specification, a thickness of an element may mean a distance between top and bottom surfaces of the element that is measured in a direction perpendicular to the top surface of the first redistribution substrate 100.

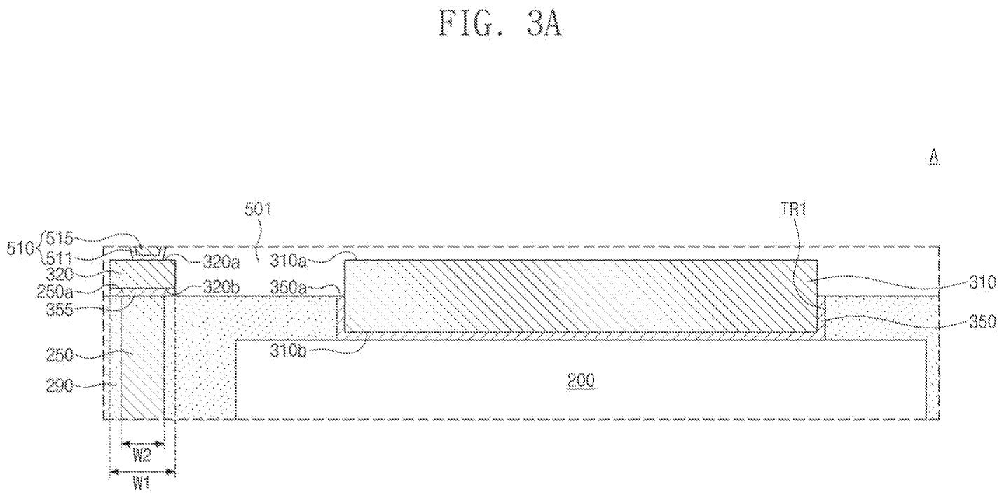

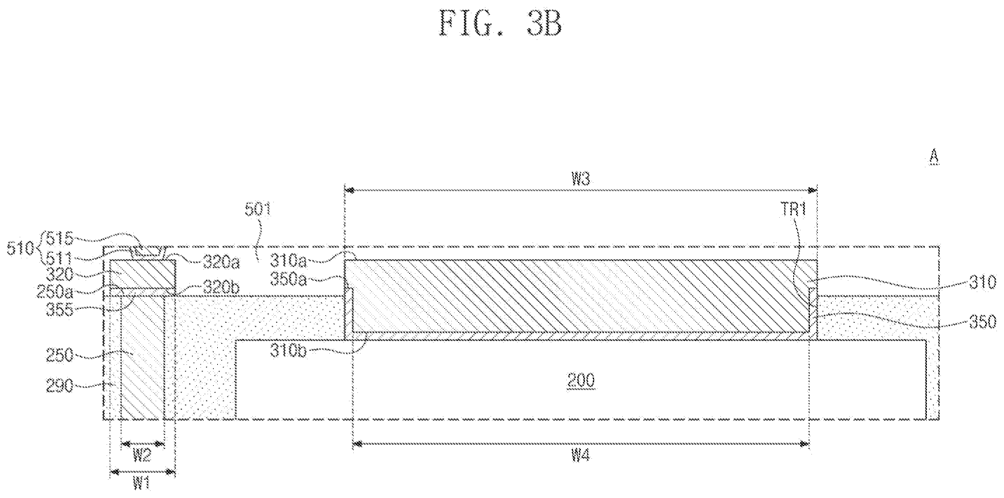

FIG. 3A is an enlarged sectional view illustrating a portion A of FIG. 2. Hereinafter, an example of the semiconductor package 1 will be described in more detail with reference to FIG. 3A.

Referring to FIGS. 1, 2, and 3A, a width W1 of a bottom surface of the heat-dissipation pad 320 may be larger than a width W2 of the conductive structure 250. For example, a difference between the width W1 of the bottom surface of the heat-dissipation pad 320 and the width W2 of the conductive structure 250 may range from 2 μm to 30 μm. In an embodiment, the difference between the width W1 of the bottom surface of the heat-dissipation pad 320 and the width W2 of the conductive structure 250 may range from 10 μm to 20 μm. In an embodiment, the heat-dissipation pad 320 may have a uniform width; for example, a width of a top surface of the heat-dissipation pad 320 may be substantially equal to the width W1 of the bottom surface of the heat-dissipation pad 320. In addition, the first heat-dissipation pattern 310 may have a uniform width. For example, a width of an upper portion of the first heat-dissipation pattern 310 may be substantially equal to a width of a lower portion of the first heat-dissipation pattern 310.

The first protection pattern 350 may be provided to conformally cover an inner side surface and a bottom surface of the first trench TR1. The first heat-dissipation pattern 310 may fill a remaining portion of the first trench TR1. The first protection pattern 350 may be disposed in the first mold layer 290, and the pad protection pattern 355 may be disposed on the first mold layer 290. The topmost surface 350a of the first protection pattern 350 may be located at a level lower than the top surface of the pad protection pattern 355. The top surface of the pad protection pattern 355 may correspond to the bottom surface 320b of the heat-dissipation pad 320. The topmost surface 350a of the first protection pattern 350 may be coplanar with a top surface of the first mold layer 290.

FIG. 3B is an enlarged sectional view illustrating the portion A of FIG. 2. Hereinafter, another example of the semiconductor package 1 will be described in more detail with reference to FIG. 3B.

Referring to FIGS. 1, 2, and 3B, the width W1 of the bottom surface of the heat-dissipation pad 320 may be larger than the width W2 of the conductive structure 250. For example, a difference between the width W1 of the bottom surface of the heat-dissipation pad 320 and the width W2 of the conductive structure 250 may range from 2 μm to 30 μm. In an embodiment, the difference between the width W1 of the bottom surface of the heat-dissipation pad 320 and the width W2 of the conductive structure 250 may range from 10 μm to 20 μm. In an embodiment, a width W3 of the upper portion of the first heat-dissipation pattern 310 may be different from a width W4 of the lower portion of the first heat-dissipation pattern 310. For example, the width W3 of the upper portion of the first heat-dissipation pattern 310 may be larger than the width W4 of the lower portion of the first heat-dissipation pattern 310.

The first protection pattern 350 may be provided to conformally cover an inner side surface and a bottom surface of the first trench TR1. The first protection pattern 350 may be extended into the second insulating layer 501. The topmost surface 350a of the first protection pattern 350 may be provided at a level higher than the top surface of the first mold layer 290. The first heat-dissipation pattern 310 may fill a remaining portion of the first trench TR1. The first protection pattern 350 may be disposed in the first mold layer 290 and the second insulating layer 501, and the pad protection pattern 355 may be disposed on the first mold layer 290. The topmost surface 350a of the first protection pattern 350 may be located at substantially the same level as the top surface of the pad protection pattern 355. The top surface of the pad protection pattern 355 may correspond to the bottom surface 320b of the heat-dissipation pad 320.

In general, heat, which is produced in a lower semiconductor chip, may be trapped in a region adjacent to a top surface of the lower semiconductor chip, and this may lead to an increase of an internal temperature of a semiconductor package and deterioration in operational characteristics of the semiconductor package.

According to an embodiment of the inventive concept, the first heat-dissipation pattern 310 may be disposed on the lower semiconductor chip 200, which is a main heat generation source, and the heat-dissipation pad 320 may be disposed on the conductive structure 250. Accordingly, heat, which is generated from the lower semiconductor chip 200, may be effectively dissipated to the outside through the first heat-dissipation pattern 310 and the heat-dissipation pad 320. As a result, it may be possible to improve heat-dissipation and operation characteristics of the semiconductor package.

Furthermore, the first protection pattern 350 may be interposed between the lower semiconductor chip 200 and the first heat-dissipation pattern 310, and the pad protection pattern 355 may be interposed between the conductive structure 250 and the heat-dissipation pad 320. The first protection pattern 350 and the pad protection pattern 355 may prevent a metal material in the second redistribution pattern 510 from being diffused into the lower semiconductor chip 200 and the conductive structure 250 during a subsequent thermal process.

Referring back to FIGS. 1 and 2, the second redistribution pattern 510 may be disposed on the first heat-dissipation pattern 310 and the heat-dissipation pads 320. In an embodiment, a plurality of the second redistribution patterns 510 may be provided. The second redistribution patterns 510 may be stacked. However, the stacked number of the second redistribution patterns 510 is not limited to that in the illustrated example and may be variously changed. In an embodiment, the second redistribution patterns 510 may be electrically connected to corresponding ones of the conductive structure 250 through the heat-dissipation pads 320. Each of the second redistribution patterns 510 may include a second seed pattern 511 and a second conductive pattern 515.

The second conductive pattern 515 may be disposed on the second seed pattern 511. The second conductive pattern 515 may include a second via portion and a second wire portion on the second via portion. The second wire portion and the second via portion may be connected to each other without any interface. For example, the second wire portion and the second via portion may be in material continuity with one another. The second wire portion may have a long axis that is horizontally extended. For example, a width of the second wire portion may be larger than a width of the second via portion. The second via portion may have a shape protruding toward a bottom surface of the second redistribution substrate 500. The second via portion may be provided in a corresponding one of the second insulating layers 501, and the second wire portion may be extended to a region on a top surface of the corresponding one of the second insulating layers 501. The second conductive pattern 515 may be formed of or may include at least one of conductive metal materials (e.g., copper (Cu)).

The second seed pattern 511 may be provided on a bottom surface of the second conductive pattern 515. The second seed pattern 511 may be interposed between the second conductive pattern 515 and the second insulating layer 501. The second seed pattern 511 may be formed of or may include at least one of conductive metal materials (e.g., copper (Cu), titanium (Ti), and/or alloys thereof).

The second pad structure 520 may be provided on the uppermost one of the second redistribution patterns 510. In an embodiment, a plurality of the second pad structures 520 may be provided to be horizontally spaced apart from each other. The second pad structures 520 may have top surfaces that are exposed to the outside of the second insulating layer 501 near the top surface of the second insulating layer 501. The second pad structures 520 may be electrically connected to at least one of the second redistribution patterns 510. Each of the second pad structures 520 may include a second pad seed pattern 521 and a second pad conductive pattern 525.

The second pad conductive pattern 525 may be disposed on the second pad seed pattern 521. The second pad conductive pattern 525 may include a second pad via portion and a second pad wire portion on the second pad via portion. The second pad wire portion and the second pad via portion may be connected to each other without an interface therebetween. For example, the second pad wire portion and the second pad via portion may be in material continuity with one another. The second pad wire portion may have a long axis that is horizontally extended. For example, a width of the second pad wire portion may be larger than a width of the second pad via portion. The second pad via portion may have a shape protruding toward the bottom surface of the second redistribution substrate 500. The second pad via portion may be provided in the uppermost one of the second insulating layers 501, and the second pad wire portion may be extended to a region on a top surface of the uppermost one of the second insulating layers 501. The second pad conductive pattern 525 may be formed of or may include at least one of conductive metal materials (e.g., copper (Cu)).

The second pad seed pattern 521 may be provided on a bottom surface of the second pad conductive pattern 525. The second pad seed pattern 521 may be interposed between the second pad conductive pattern 525 and the second insulating layer 501. The second pad seed pattern 521 may be formed of or may include at least one of conductive metal materials (e.g., copper (Cu), titanium (Ti), and/or alloys thereof).

The upper semiconductor chip 600 may be mounted on a top surface of the second redistribution substrate 500. The upper semiconductor chip 600 may be a memory chip, a logic chip, or a sensing chip, but the inventive concept is not limited to this example. The memory chip may be one of, for example, DRAM, SRAM, MRAM, and FLASH memory chips. The upper semiconductor chip 600 may include second chip pads 610 provided near a bottom surface thereof. The second chip pads 610 may be electrically connected to integrated circuits of the upper semiconductor chip 600 through interconnection lines in the upper semiconductor chip 600. The second chip pads 610 may be formed of or may include at least one of conductive metal materials (e.g., copper (Cu)).

A second connection terminal 620 may be provided on the second redistribution substrate 500. The second connection terminal 620 may be disposed on the second pad structure 520. In an embodiment, a plurality of the second connection terminals 620 may be provided to be horizontally spaced apart from each other. The second connection terminals 620 may be interposed between the second redistribution substrate 500 and the upper semiconductor chip 600. The second connection terminals 620 may be interposed between and electrically connected to the second pad structures 520 and the second chip pads 610. The upper semiconductor chip 600 may be electrically connected to the second redistribution substrate 500 through the second connection terminals 620. Each of the second connection terminals 620 may be in contact with a top surface of the second pad structure 520 and a bottom surface of the second chip pad 610. The second connection terminals 620 may be provided in the form of at least one of solder balls, solder pillars, and solder bumps. The second connection terminals 620 may include a conductive metal material. For example, the second connection terminals 620 may be formed of or may include at least one of tin (Sn), lead (Pb), nickel (Ni), gold (Au), silver (Ag), copper (Cu), aluminum (Al), or bismuth (Bi).

A second mold layer 690 may be provided on the second redistribution substrate 500. The second mold layer 690 may cover the top surface of the second redistribution substrate 500 and the upper semiconductor chip 600. The second mold layer 690 may cover top and side surfaces of the upper semiconductor chip 600. The second mold layer 690 may be interposed between the second connection terminals 620 to cover the second connection terminals 620. The second mold layer 690 may be formed of or may include at least one of for example, insulating polymers (e.g., epoxy molding compounds).

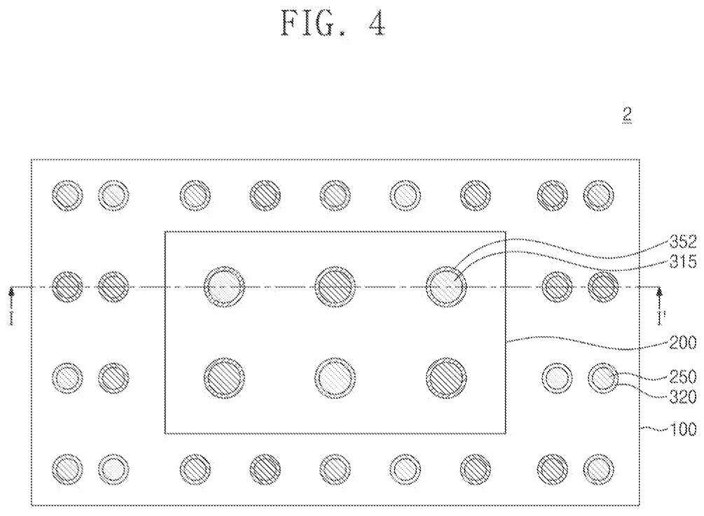

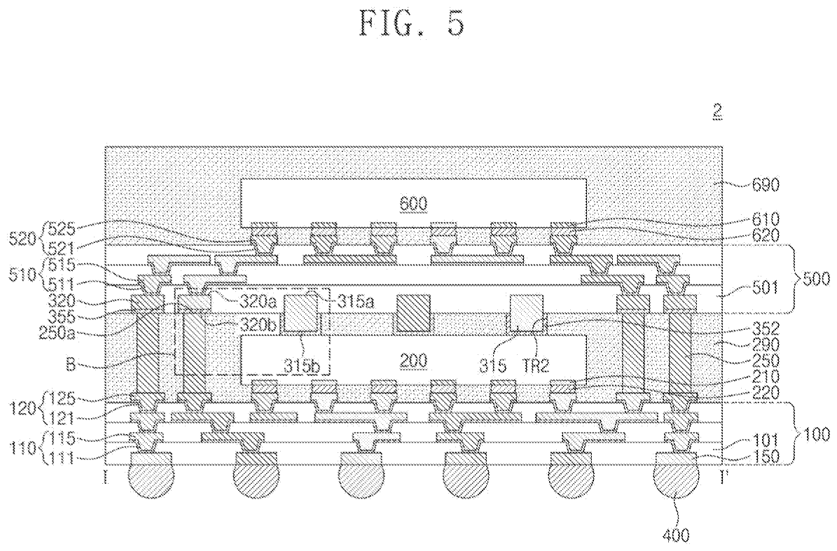

FIG. 4 is a plan view illustrating a semiconductor package according to an example embodiment of the inventive concept. FIG. 5 is a sectional view, which is taken along a line I-I′ of FIG. 4 to illustrate a semiconductor package according to an example embodiment of the inventive concept. For concise description, previously described elements may be identified by the same reference numbers without repeating an overlapping description thereof.

Referring to FIGS. 4 and 5, a semiconductor package 2 may include the first redistribution substrate 100, the lower semiconductor chip 200, the upper semiconductor chip 600, a second heat-dissipation pattern 315, the heat-dissipation pad 320, and the second redistribution substrate 500.

The first redistribution substrate 100 may include the first insulating layers 101, the first redistribution patterns 110, the first pad structures 120, and the under-bump patterns 150 which are stacked. The outer terminal 400 may be provided on the bottom surface of the first redistribution substrate 100.

The lower semiconductor chip 200 may be mounted on the top surface of the first redistribution substrate 100. The lower semiconductor chip 200 may include the first chip pads 210 provided near a bottom surface thereof. The first connection terminals 220 may be interposed between the first pad structures 120 and the first chip pads 210.

The conductive structures 250 may be disposed on the top surface of the first redistribution substrate 100. The first mold layer 290 may be provided on the first redistribution substrate 100 to cover the lower semiconductor chip 200 and the conductive structures 250. The first mold layer 290 may be provided to have second trenches TR2 exposing portions of the top surface of the lower semiconductor chip 200.

The second redistribution substrate 500 may be provided on the first redistribution substrate 100. The second redistribution substrate 500 may include the second insulating layers 501, the second redistribution patterns 510, and the second pad structures 520 which are stacked on the first redistribution substrate 100. The second redistribution patterns 510 may be disposed on the second heat-dissipation patterns 315 and the heat-dissipation pads 320.

The second heat-dissipation pattern 315 may be provided on the lower semiconductor chip 200. In an embodiment, a plurality of the second heat-dissipation patterns 315 may be provided. The second heat-dissipation patterns 315 may be interposed between the lower semiconductor chip 200 and the second insulating layer 501. The second heat-dissipation patterns 315 may be disposed in the second trenches TR2, respectively. For example, bottom surfaces of the second heat-dissipation patterns 315 may be at a lower vertical level than a top surface of the first mold layer 290, and top surfaces of the second heat-dissipation patterns 315 may be at a higher vertical level than a top surface of the first mold layer 290. The second heat-dissipation patterns 315 may be disposed on the bottom surface of the second redistribution pattern 510. The second heat-dissipation patterns 315 may be disposed at a level different from the second redistribution pattern 510. For example, bottom surfaces of the second heat-dissipation patterns 315 may be at a lower vertical level than a bottom surface of the second redistribution pattern 510, and top surfaces of the second heat-dissipation patterns 315 may be at a higher vertical level than the bottom surface of the second redistribution pattern 510. The second heat-dissipation patterns 315 and the second wire portion of the second redistribution pattern 510 may be disposed in different ones of the second insulating layers 501. The second heat-dissipation patterns 315 may be disposed on the center region of the first redistribution substrate 100, when viewed in a plan view. The second heat-dissipation pattern 315 may be provided to have a circular shape, when viewed in a plan view. However, the inventive concept is not limited to this example, and unlike the illustrated structure, the second heat-dissipation pattern 315 may have a rectangular or polygonal shape, when viewed in a plan view. The second heat-dissipation pattern 315 may be formed of or may include at least one of conductive metal materials (e.g., copper (Cu)).

A second protection pattern 352 may be provided on a bottom surface 315b of each of the second heat-dissipation patterns 315. The second protection pattern 352 may cover a lower portion of the second heat-dissipation pattern 315. The second protection pattern 352 may cover the bottom surface 315b and lower side surfaces of the second heat-dissipation pattern 315. For example, each of the second protection patterns 352 may contact the bottom surface 315b and the lower side surface of a corresponding one of the second heat-dissipation patterns 315. The second protection pattern 352 may be interposed between the lower side surface of the second heat-dissipation pattern 315 and the first mold layer 290 and between the bottom surface 315b of the second heat-dissipation pattern 315 and the lower semiconductor chip 200. The second protection pattern 352 may be provided to expose a top surface 315a and upper side surfaces of the second heat-dissipation pattern 315. The second protection pattern 352 and the second heat-dissipation pattern 315 may be formed of or may include different materials from each other. The second protection pattern 352 may be formed of or may include at least one of conductive metal materials (e.g., titanium (Ti)).

The heat-dissipation pads 320 may be disposed on the first mold layer 290. The heat-dissipation pads 320 may be disposed in the second insulating layer 501. The heat-dissipation pads 320 may be spaced apart from the second heat-dissipation patterns 315. The heat-dissipation pad 320 may have a circular shape, when viewed in a plan view. However, the inventive concept is not limited to this example, and unlike the illustrated structure, the heat-dissipation pad 320 may have a rectangular or polygonal shape, when viewed in a plan view. The heat-dissipation pad 320 may be formed of or may include the same material as the second heat-dissipation pattern 315. The pad protection pattern 355 may be disposed on the bottom surface 320b of each of the heat-dissipation pads 320. The pad protection pattern 355 may be formed of or may include the same material as the second protection pattern 352.

The top surfaces 315a of the second heat-dissipation patterns 315 and the top surfaces 320a of the heat-dissipation pads 320 may be located at a level higher than the top surface 250a of the conductive structure 250. The top surfaces 315a of the second heat-dissipation patterns 315 may be located at substantially the same level as the top surface 320a of the heat-dissipation pad 320. The bottom surfaces 315b of the second heat-dissipation patterns 315 may be located at a level lower than the bottom surface 320b of the heat-dissipation pad 320. A thickness of the second heat-dissipation pattern 315 may be larger than a thickness of the heat-dissipation pad 320.

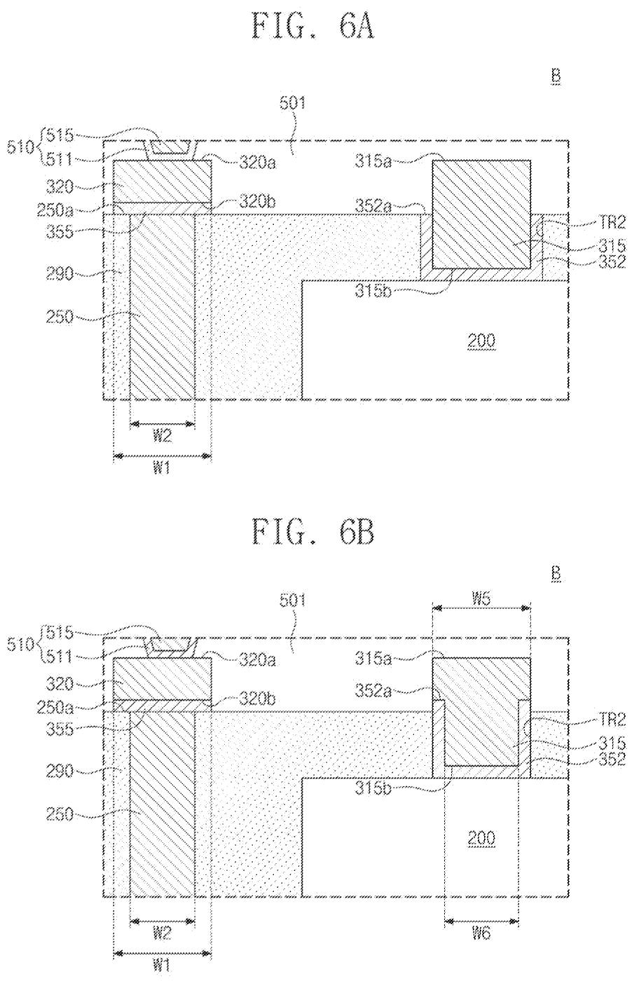

FIG. 6A is an enlarged sectional view illustrating a portion B of FIG. 5. Hereinafter, an example of the semiconductor package 2 will be described in more detail with reference to FIG. 6A.

Referring to FIGS. 4, 5, and 6A, the width W1 of the bottom surface of the heat-dissipation pad 320 may be larger than the width W2 of the conductive structure 250. For example, a difference between the width W1 of the bottom surface of the heat-dissipation pad 320 and the width W2 of the conductive structure 250 may range from 2 μm to 30 μm or from 10 μm to 20 μm. In an embodiment, the second heat-dissipation pattern 315 may have a uniform width. For example, a width of an upper portion of the second heat-dissipation pattern 315 may be substantially equal to a width of the lower portion of the second heat-dissipation pattern 315.

The second protection pattern 352 may conformally cover an inner side surface and a bottom surface of the second trench TR2. The second heat-dissipation pattern 315 may fill a remaining portion of the first trench TR1. The second protection pattern 352 may be disposed in the first mold layer 290, and the pad protection pattern 355 may be disposed on the first mold layer 290. The topmost surface 352a of the second protection pattern 352 may be located at a level lower than the top surface of the pad protection pattern 355. In example embodiments, the topmost surface 352a of the second protection pattern 352 may be coplanar with a top surface of the first mold layer 290. The top surface of the pad protection pattern 355 may correspond to the bottom surface 320b of the heat-dissipation pad 320.

FIG. 6B is an enlarged sectional view illustrating the portion B of FIG. 5. Hereinafter, another example of the semiconductor package 2 will be described in more detail with reference to FIG. 6B.

Referring to FIGS. 4, 5, and 6B, the width W1 of the bottom surface of the heat-dissipation pad 320 may be larger than the width W2 of the conductive structure 250. For example, a difference between the width W1 of the bottom surface of the heat-dissipation pad 320 and the width W2 of the conductive structure 250 may range from 2 μm to 30 μm or from 10 μm to 20 μm. Furthermore, a width W5 of the upper portion of the second heat-dissipation pattern 315 may be different from a width W6 of the lower portion of the second heat-dissipation pattern 315. For example, the width W5 of the upper portion of the second heat-dissipation pattern 315 may be larger than the width W6 of the lower portion of the second heat-dissipation pattern 315.

The second protection pattern 352 may conformally cover an inner side surface and a bottom surface of the second trench TR2. The second protection pattern 352 may be extended into the second insulating layer 501. The topmost surface 352a of the second protection pattern 352 may be provided at a level higher than the top surface of the first mold layer 290. The second heat-dissipation pattern 315 may fill a remaining portion of the second trench TR2. The second protection pattern 352 may be disposed in the first mold layer 290 and the second insulating layer 501, and the pad protection pattern 355 may be disposed on the first mold layer 290. The topmost surface 352a of the second protection pattern 352 may be positioned at substantially the same level as the top surface of the pad protection pattern 355. The top surface of the pad protection pattern 355 may correspond to the bottom surface 320b of the heat-dissipation pad 320.

According to an embodiment of the inventive concept, the second heat-dissipation pattern 315 may be disposed on the lower semiconductor chip 200, which is a main heat generation source, and the heat-dissipation pad 320 may be disposed on the conductive structure 250. Accordingly, heat, which is generated from the lower semiconductor chip 200, may be effectively dissipated to the outside through the second heat-dissipation pattern 315 and the heat-dissipation pad 320. As a result, it may be possible to improve heat-dissipation and operation characteristics of the semiconductor package.

Furthermore, the second protection pattern 352 may be interposed between the lower semiconductor chip 200 and the second heat-dissipation pattern 315, and the pad protection pattern 355 may be interposed between the conductive structure 250 and the heat-dissipation pad 320. The second protection pattern 352 and the pad protection pattern 355 may prevent a metal material in the second redistribution pattern 510 from being diffused into the lower semiconductor chip 200 and the conductive structure 250 during a subsequent thermal process.

Referring back to FIGS. 4 and 5, the upper semiconductor chip 600 may be mounted on the top surface of the second redistribution substrate 500. The upper semiconductor chip 600 may include the second chip pads 610 provided near a bottom surface thereof. The second connection terminals 620 may be interposed between the second pad structures 520 and the second chip pads 610. The second mold layer 690 may be provided on the second redistribution substrate 500 to cover the upper semiconductor chip 600.

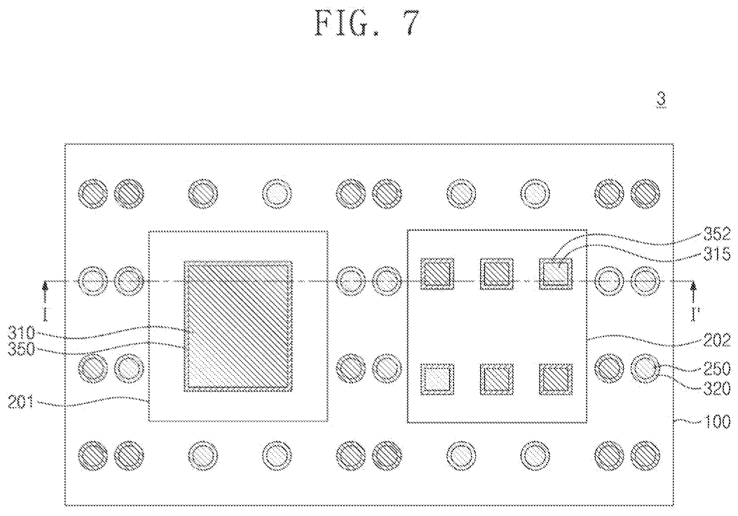

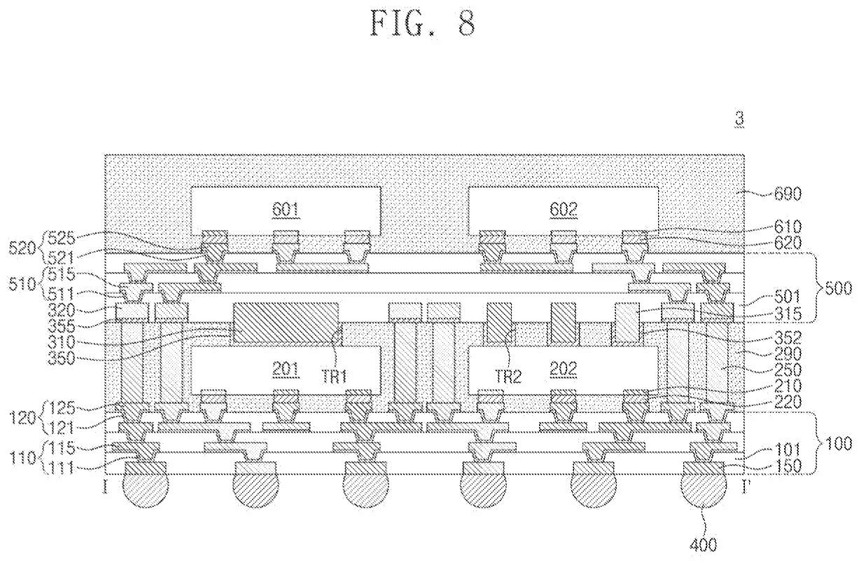

FIG. 7 is a plan view illustrating a semiconductor package according to an example embodiment of the inventive concept. FIG. 8 is a sectional view, which is taken along a line I-I′ of FIG. 7 to illustrate a semiconductor package according to an example embodiment of the inventive concept. For concise description, previously described elements may be identified by the same reference numbers without repeating an overlapping description thereof.

Referring to FIGS. 7 and 8, a semiconductor package 3 may include the first redistribution substrate 100, a first lower semiconductor chip 201, a second lower semiconductor chip 202, a first upper semiconductor chip 601, a second upper semiconductor chip 602, the first heat-dissipation pattern 310, the second heat-dissipation patterns 315, the heat-dissipation pads 320, and the second redistribution substrate 500.

The first redistribution substrate 100 may include the first insulating layers 101, the first redistribution patterns 110, the first pad structures 120, and the under-bump patterns 150 which are stacked. The outer terminal 400 may be provided on the bottom surface of the first redistribution substrate 100.

The first and second lower semiconductor chips 201 and 202 may be mounted on the top surface of the first redistribution substrate 100. The first lower semiconductor chip 201 may be horizontally spaced apart from the second lower semiconductor chip 202. Each of the first and second lower semiconductor chips 201 and 202 may be a memory chip, a logic chip, or a sensing chip, but the inventive concept is not limited to this example. The memory chip may be one of, for example, DRAM, SRAM, MRAM, and FLASH memory chips. Each of the first and second lower semiconductor chips 201 and 202 may include the first chip pads 210 provided near a bottom surface thereof. The first connection terminals 220 may be interposed between the first pad structures 120 and the first chip pads 210. The first connection terminals 220 may be interposed between the first redistribution substrate 100 and the first lower semiconductor chip 201 and between the first redistribution substrate 100 and the second lower semiconductor chip 202.

The conductive structures 250 may be disposed on the top surface of the first redistribution substrate 100. The conductive structures 250 may be horizontally spaced apart from the first and second lower semiconductor chips 201 and 202. The conductive structures 250 may be arranged to enclose each of the first and second lower semiconductor chips 201 and 202, when viewed in a plan view. The first mold layer 290 may be provided on the first redistribution substrate 100 to cover the first and second lower semiconductor chips 201 and 202 and the conductive structures 250. The first mold layer 290 may be provided to have the first trench TR1, which is formed to expose a portion of a top surface of the first lower semiconductor chip 201, and the second trenches TR2, which are formed to expose portions of a top surface of the second lower semiconductor chip 202.

The second redistribution substrate 500 may be provided on the first redistribution substrate 100. The second redistribution substrate 500 may include the second insulating layers 501, the second redistribution patterns 510, and the second pad structures 520 which are stacked on the first redistribution substrate 100.

The first heat-dissipation pattern 310 may be provided on the first lower semiconductor chip 201. The first heat-dissipation pattern 310 may be interposed between the first lower semiconductor chip 201 and the second insulating layer 501. The first protection pattern 350 may be interposed between the lower side surface of the first heat-dissipation pattern 310 and the first mold layer 290 and between the first heat-dissipation pattern 310 and the first lower semiconductor chip 201. The heat-dissipation pads 320 may be disposed on the first mold layer 290. The heat-dissipation pads 320 may be spaced apart from the first heat-dissipation pattern 310 and the second heat-dissipation patterns 315. Each of the pad protection patterns 355 may be interposed between the heat-dissipation pad 320 and the conductive structure 250. The first heat-dissipation pattern 310, the first protection pattern 350, the heat-dissipation pad 320, and the pad protection pattern 355 may be configured to have substantially the same features as those described with reference to FIGS. 1, 2, and 3A or FIGS. 1, 2, and 3B.

The second heat-dissipation patterns 315 may be provided on the second lower semiconductor chip 202. The second heat-dissipation patterns 315 may be interposed between the second lower semiconductor chip 202 and the second insulating layer 501. As an example, the second heat-dissipation pattern 315 may have a rectangular shape, when viewed in a plan view. The second protection pattern 352 may be interposed between a lower side surface of the second heat-dissipation pattern 315 and the first mold layer 290 and between a bottom surface of the second heat-dissipation pattern 315 and the lower semiconductor chip 200. The second heat-dissipation patterns 315 and the second protection pattern 352 may be configured to have substantially the same features as those described with reference to FIGS. 4, 5, and 6A or FIGS. 4, 5, and 6B.

The first and second upper semiconductor chips 601 and 602 may be mounted on the top surface of the second redistribution substrate 500. The first upper semiconductor chip 601 may be horizontally spaced apart from the second upper semiconductor chip 602. The first and second upper semiconductor chips 601 and 602 may vertically overlap the first and second lower semiconductor chips 201 and 202. The first and second upper semiconductor chips 601 and 602 may be a memory chip, a logic chip, or a sensing chip, but the inventive concept is not limited to this example. The memory chip may be one of, for example, DRAM, SRAM, MRAM, and FLASH memory chips. Each of the first and second upper semiconductor chips 601 and 602 may include the second chip pads 610 provided near a bottom surface thereof.

The second connection terminals 620 may be interposed between the second pad structures 520 and the second chip pads 610. The second connection terminals 620 may be interposed between the second redistribution substrate 500 and the first upper semiconductor chip 601 and between the second redistribution substrate 500 and the second upper semiconductor chip 602. The second mold layer 690 may be provided on the second redistribution substrate 500 to cover the first and second upper semiconductor chips 601 and 602.

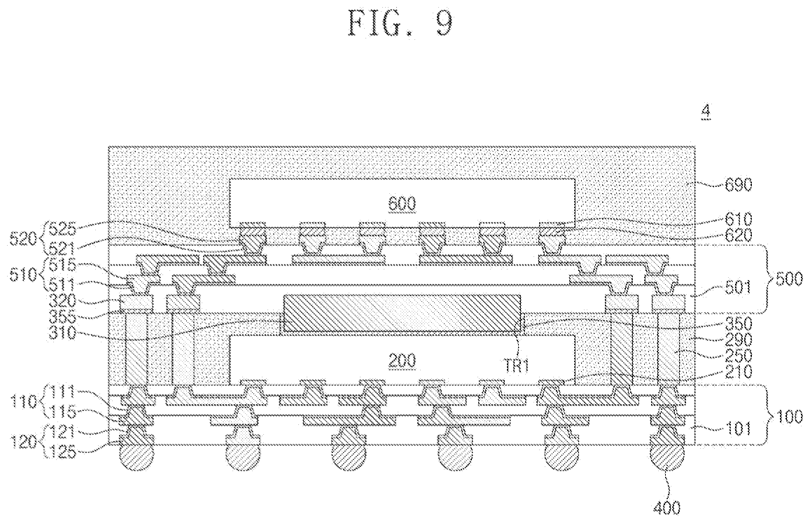

FIG. 9 is a sectional view illustrating a semiconductor package according to an example embodiment of the inventive concept. For concise description, a previously described element may be identified by the same reference number without repeating an overlapping description thereof.

Referring to FIG. 9, a semiconductor package 4 may include the first redistribution substrate 100, the lower semiconductor chip 200, the upper semiconductor chip 600, the first heat-dissipation pattern 310, the heat-dissipation pad 320, and the second redistribution substrate 500.

The first redistribution substrate 100 may include the first insulating layers 101, the first redistribution patterns 110, and the first pad structures 120 which are stacked. The outer terminal 400 may be provided on the bottom surface of the first redistribution substrate 100.

Each of the first redistribution patterns 110 may include the first seed pattern 111 and the first conductive pattern 115. The first seed pattern 111 may be disposed on the first conductive pattern 115. The first conductive pattern 115 may include a first wire portion and a first via portion on the first wire portion. The first via portion may have a shape protruding toward the top surface of the first redistribution substrate 100. For example, a width of the first via portion may narrow as the first via portion extends toward the top surface of the first redistribution substrate 100. The first pad structures 120 may be disposed adjacent to the bottom surface of the first redistribution substrate 100. The first pad structures 120 may be disposed on bottom surfaces of the lowermost ones of the first redistribution patterns 110. Bottom surfaces of the first pad structures 120 may be exposed to the outside of the first insulating layer 101 near a bottom surface of the first insulating layer 101. Each of the first pad structures 120 may include the first pad conductive pattern 125 and the first pad seed pattern 121 on the first pad conductive pattern 125. The first pad conductive pattern 125 may include a first pad wire portion and a first pad via portion on the first pad wire portion.

The lower semiconductor chip 200 may be mounted on the top surface of the first redistribution substrate 100. The lower semiconductor chip 200 may include the first chip pads 210 provided near a bottom surface thereof. The first chip pads 210 may contact the first seed patterns 111. The conductive structures 250 may be disposed on the top surface of the first redistribution substrate 100. The first mold layer 290 may be provided on the first redistribution substrate 100 to cover the lower semiconductor chip 200 and the conductive structures 250.

The second redistribution substrate 500 may be provided on the first redistribution substrate 100. The second redistribution substrate 500 may include the second insulating layers 501, the second redistribution patterns 510, and the second pad structures 520 which are stacked on the first redistribution substrate 100.

The first heat-dissipation pattern 310 may be interposed between the lower semiconductor chip 200 and the second insulating layer 501. The first protection pattern 350 may be interposed between a lower side surface of the first heat-dissipation pattern 310 and the first mold layer 290 and between the first heat-dissipation pattern 310 and the lower semiconductor chip 200. The heat-dissipation pads 320 may be disposed on the first mold layer 290. Each of the pad protection patterns 355 may be interposed between the heat-dissipation pad 320 and the conductive structure 250.

The upper semiconductor chip 600 may be mounted on the top surface of the second redistribution substrate 500. The upper semiconductor chip 600 may include second chip pads 610 provided near a bottom surface thereof. The second connection terminals 620 may be interposed between the second pad structures 520 and the second chip pads 610. The second mold layer 690 may be disposed on the second redistribution substrate 500 to cover the upper semiconductor chip 600.

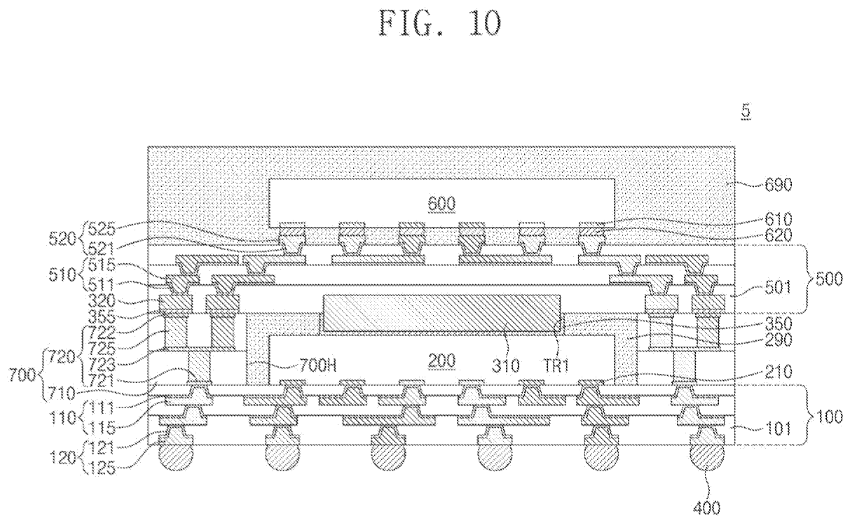

FIG. 10 is a sectional view illustrating a semiconductor package according to an example embodiment of the inventive concept. For concise description, previously described elements may be identified by the same reference numbers without repeating an overlapping description thereof.

Referring to FIG. 10, a semiconductor package 5 may include the first redistribution substrate 100, the lower semiconductor chip 200, the upper semiconductor chip 600, the first heat-dissipation pattern 310, the heat-dissipation pad 320, and the second redistribution substrate 500.

The first redistribution substrate 100 may include the first insulating layers 101, the first redistribution patterns 110, and the first pad structures 120 which are stacked. The outer terminal 400 may be provided on the bottom surface of the first redistribution substrate 100. The first redistribution substrate 100 may be configured to have substantially the same features as that described with reference to FIG. 9.

A connection substrate 700 may be disposed on the first redistribution substrate 100. The connection substrate 700 may be provided to have a connection hole 700H penetrating the same. The connection substrate 700 may include a base layer 710 and a connection structure 720. The base layer 710 may include a single layer or a plurality of stacked layers. The base layer 710 may be formed of or may include at least one of insulating materials and may include, for example, carbon-based materials (e.g., graphite or graphene), ceramics, or polymeric materials (e.g., nylon, polycarbonate, or polyethylene). The connection hole 700H may be provided to penetrate the base layer 710.

The connection structure 720 may be provided in the base layer 710. The connection structure 720 may be spaced apart from the lower semiconductor chip 200. The connection structure 720 may be electrically connected to the first redistribution substrate 100. Accordingly, the connection structure 720 may be electrically connected to the lower semiconductor chip 200 or the outer terminals 400 through the first redistribution substrate 100. In an embodiment, the connection structure 720 may be formed of or may include at least one of conductive metal materials (e.g., copper (Cu), aluminum (Al), tungsten (W), titanium (Ti), stainless steel (SUS), iron (Fe), and alloys thereof).

The connection structure 720 may include a first pad 721, a second pad 722, a third pad 723, and vias 725. In some embodiments, the first pad 721, the second pad 722, and the third pad 723 may be a plurality of first pads 721, a plurality of second pads 722, and a plurality of third pads 723, respectively. The first pad 721 may be exposed to the outside of the connection substrate 700 near a bottom surface of the connection substrate 700. The third pad 723 may be interposed between the base layers 710. The vias 725 may be provided to penetrate the base layers 710 and may be coupled to the third pad 723. The second pad 722 may be exposed to the outside of the connection substrate 700 near a top surface of the connection substrate 700 and may be coupled to one of the vias 725. The second pad 722 may be electrically connected to the first pad 721 through the vias 725 and the third pad 723.

The lower semiconductor chip 200 may be mounted on the top surface of the first redistribution substrate 100. The lower semiconductor chip 200 may be disposed in the connection hole 700H of the connection substrate 700. The lower semiconductor chip 200 may include the first chip pads 210 provided near a bottom surface thereof. The first chip pads 210 may contact the first seed patterns 111.

The first mold layer 290 may be provided on the first redistribution substrate 100 to cover the lower semiconductor chip 200 and the conductive structures 250.

The second redistribution substrate 500 may be provided on the first redistribution substrate 100. The second redistribution substrate 500 may include the second insulating layers 501, the second redistribution patterns 510, and the second pad structures 520 which are stacked on the first redistribution substrate 100.

The first heat-dissipation pattern 310 may be interposed between the lower semiconductor chip 200 and the second insulating layer 501. The first protection pattern 350 may be interposed between a lower side surface of the first heat-dissipation pattern 310 and the first mold layer 290 and between the first heat-dissipation pattern 310 and the lower semiconductor chip 200. The heat-dissipation pads 320 may be disposed on the first mold layer 290. Each of the pad protection patterns 355 may be interposed between the heat-dissipation pad 320 and the conductive structure 250.

The upper semiconductor chip 600 may be mounted on the top surface of the second redistribution substrate 500. The upper semiconductor chip 600 may include second chip pads 610 provided near a bottom surface thereof. The second connection terminals 620 may be interposed between the second pad structures 520 and the second chip pads 610. The second mold layer 690 may be provided on the second redistribution substrate 500 to cover the upper semiconductor chip 600.

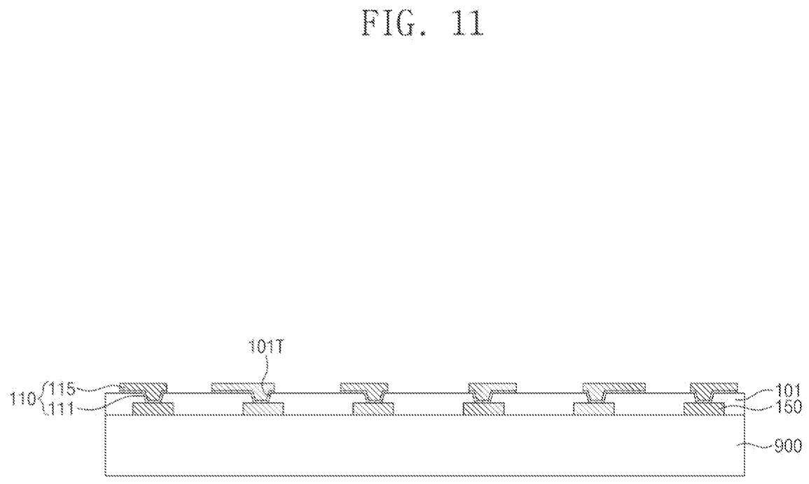

FIGS. 11 to 18 are sectional views illustrating a method of fabricating a semiconductor package according to an example embodiment of the inventive concept. For concise description, previously described elements may be identified by the same reference numbers without repeating an overlapping description thereof.

Referring to FIG. 11, a carrier substrate 900 may be provided. The under-bump patterns 150 may be formed on the carrier substrate 900. In an embodiment, the under-bump patterns 150 may be formed of or include by an electroplating process. The first insulating layer 101 may be formed on the carrier substrate 900 to cover the under-bump patterns 150. Openings 101T may be formed in the first insulating layer 101 to expose the under-bump patterns 150.

The first redistribution patterns 110 may be formed. The formation of the first redistribution patterns 110 may include forming the first seed patterns 111 and the first conductive patterns 115. The formation of the first seed patterns 111 and the first conductive patterns 115 may include forming a first seed layer in the openings 101T and on a top surface of the first insulating layer 101, forming a resist pattern (not shown) on the first seed layer, performing an electroplating process using the first seed layer as an electrode to form the first conductive patterns 115, removing the resist pattern, and performing an etching process to remove an exposed portion of the first seed layer. As a result of the electroplating process, each of the first conductive patterns 115 may include a first via portion, which is formed in the opening 101T, and a first wire portion, which is formed on the first insulating layer 101. The first seed patterns 111 may be formed by the etching process. The resist pattern may be removed by, for example, a strip process.

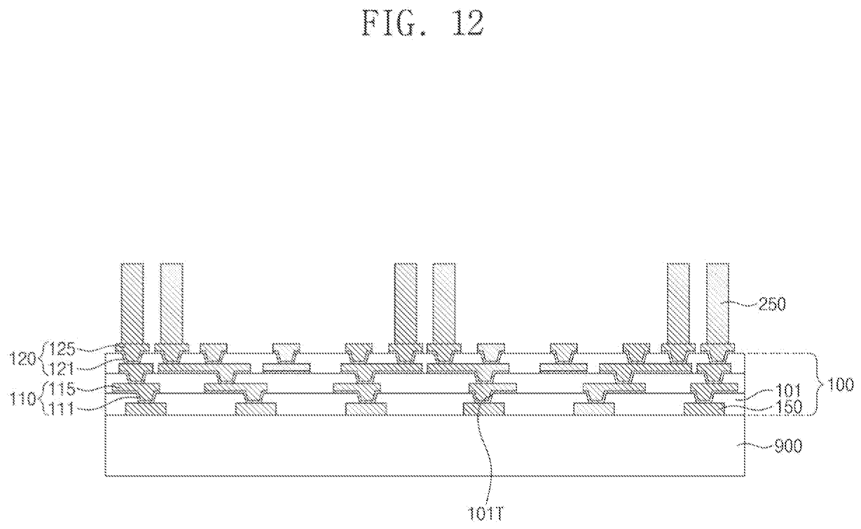

Referring to FIG. 12, a plurality of first insulating layers 101 and a plurality of first redistribution patterns 110 may be additionally stacked on the structure of FIG. 11. The first insulating layers 101 and the first redistribution patterns 110 may be formed by repeating the process described with reference to FIG. 11. The first pad structures 120 may be formed on the uppermost ones of the first redistribution patterns 110.

The formation of the first pad structures 120 may include forming the first pad seed patterns 121 and the first pad conductive patterns 125. The first pad seed patterns 121 may be formed by the same method as that for the first seed patterns 111 described with reference to FIG. 11. The first pad conductive patterns 125 may be formed by the same method as that for the first conductive patterns 115 described with reference to FIG. 11. As a result, the first redistribution substrate 100 may be formed. Next, the conductive structures 250 may be formed on the first redistribution substrate 100.

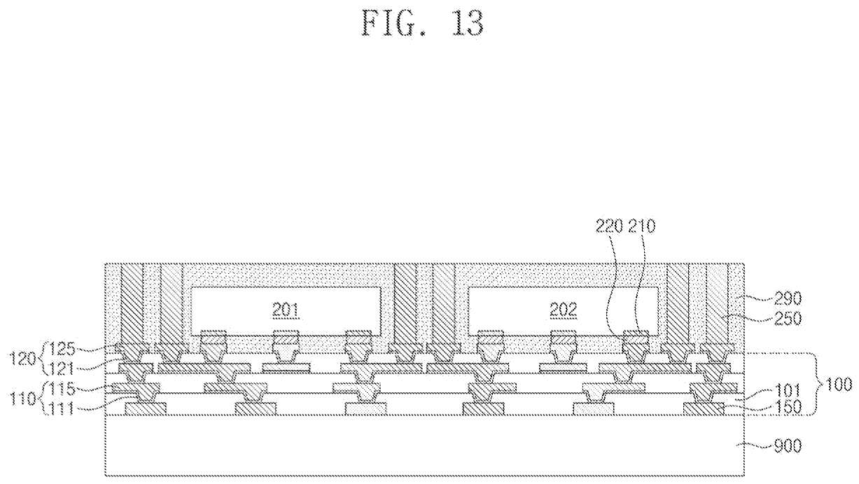

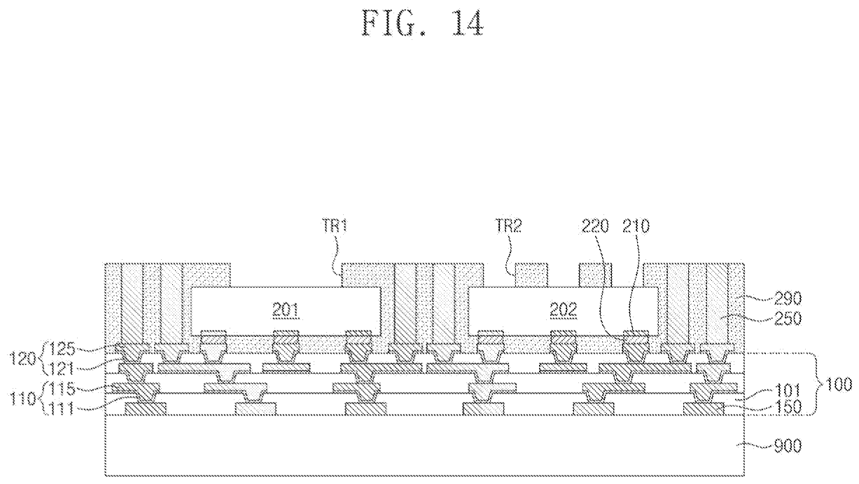

Referring to FIG. 13, the first and second lower semiconductor chips 201 and 202 may be mounted on the first redistribution substrate 100. Each of the first and second lower semiconductor chips 201 and 202 may include the first chip pads 210 provided near a bottom surface thereof. The mounting of the first lower semiconductor chip 201 may include forming the first connection terminals 220 between the first redistribution substrate 100 and the first lower semiconductor chip 201. The mounting of the second lower semiconductor chip 202 may include forming the first connection terminals 220 between the first redistribution substrate 100 and the second lower semiconductor chip 202.

The first mold layer 290 may be formed on the first redistribution substrate 100 to cover the first and second lower semiconductor chips 201 and 202. A grinding process may be performed on the first mold layer 290 to remove a portion of the first mold layer 290. As a result of the grinding process, top surfaces of the conductive structures 250 may be exposed to the outside and may be located at substantially the same level as the top surface of the first mold layer 290.

Referring to FIG. 14, the first mold layer 290 may be partially removed to form the first trench TR1, which exposes a portion of a top surface of the first lower semiconductor chip 201, and to form the second trenches TR2, which expose portions of a top surface of the second lower semiconductor chip 202. In an embodiment, the first and second trenches TR1 and TR2 may be formed by a laser grooving process.

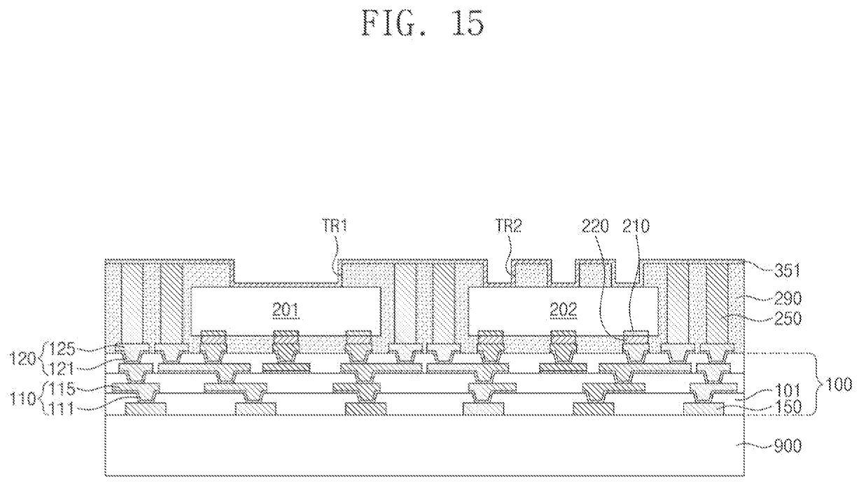

Referring to FIG. 15, a protection layer 351 may be formed on the first mold layer 290. The protection layer 351 may be formed to cover the top surface of the first mold layer 290 and the top surface of the conductive structure 250 and to conformally cover an inner side surface and a bottom surface of the first trench TR1 and inner side surfaces and bottom surfaces of the second trenches TR2.

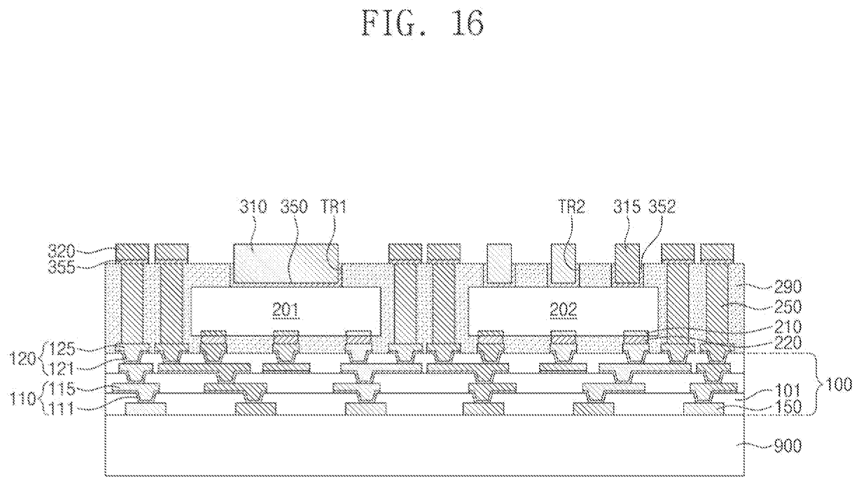

Referring to FIG. 16, the first heat-dissipation pattern 310, the second heat-dissipation patterns 315, and the heat-dissipation pads 320 may be formed on the protection layer 351. The first heat-dissipation pattern 310 may be formed to fill a remaining portion of the first trench TR1, and the second heat-dissipation patterns 315 may be formed to fill remaining portions of the second trenches TR2, respectively. In an embodiment, the first heat-dissipation pattern 310, the second heat-dissipation patterns 315, and the heat-dissipation pads 320 may be formed by an electroplating process using the protection layer 351 as a plating electrode.

An exposed portion of the protection layer 351 may be removed to form the first protection pattern 350 under a bottom surface of the first heat-dissipation pattern 310, to form the second protection patterns 352 under respective bottom surfaces of the second heat-dissipation patterns 315, and to form the pad protection patterns 355 under respective bottom surfaces of the heat-dissipation pads 320.

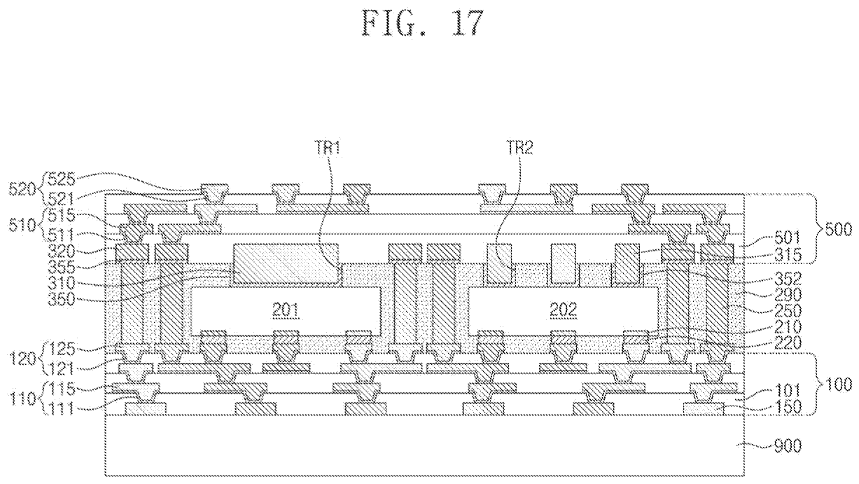

Referring to FIG. 17, the second insulating layers 501 and the second redistribution patterns 510 may be stacked on the first heat-dissipation pattern 310, the second heat-dissipation patterns 315, and the heat-dissipation pads 320. The second pad structures 520 may be formed on the uppermost ones of the second redistribution patterns 510. Accordingly, the second redistribution substrate 500 may be formed.

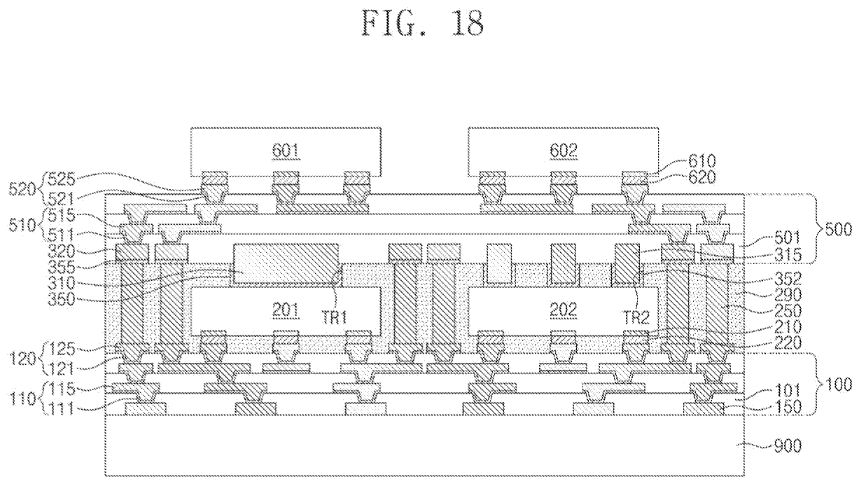

Referring to FIG. 18, the first and second upper semiconductor chips 601 and 602 may be mounted on the second redistribution substrate 500. Each of the first and second upper semiconductor chips 601 and 602 may include the second chip pads 610 provided near a bottom surface thereof. The mounting of the first upper semiconductor chip 601 may include forming the second connection terminals 620 between the second redistribution substrate 500 and the first upper semiconductor chip 601. The mounting of the second upper semiconductor chip 602 may include forming the second connection terminals 620 between the second redistribution substrate 500 and the second upper semiconductor chip 602.

Referring back to FIGS. 1 and 2, FIGS. 4 and 5, and FIGS. 7 and 8, the second mold layer 690 may be formed on the second redistribution substrate 500 to cover the first and second upper semiconductor chips 601 and 602.

The carrier substrate 900 may be removed. The outer terminals 400 may be formed on a bottom surface of the under-bump pattern 150. The formation of the outer terminals 400 may include performing a solder ball attaching process. As a result, the semiconductor package 1, semiconductor package 2, or semiconductor package 3 may be formed.

According to an embodiment of the inventive concept, a heat-dissipation pattern may be disposed on a lower semiconductor chip, which is a main heat generation source, and a heat-dissipation pad may be disposed on a conductive structure. Thus, heat, which is generated from the lower semiconductor chip, may be effectively dissipated to the outside through the heat-dissipation pattern and the heat-dissipation pad. As a result, it may be possible to improve heat-dissipation and operation characteristics of the semiconductor package.

Furthermore, a protection pattern may be interposed between the lower semiconductor chip and the heat-dissipation pattern, and a pad protection pattern may be interposed between the conductive structure and the heat-dissipation pad. The protection pattern and the pad protection pattern may prevent a metal material in a redistribution pattern thereon from being diffused into the lower semiconductor chip and the conductive structure during a subsequent thermal process.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a first redistribution substrate comprising a first insulating layer and a first redistribution pattern;
a lower semiconductor chip mounted on the first redistribution substrate;
a conductive structure disposed on the first redistribution substrate and horizontally spaced apart from the lower semiconductor chip;
a second redistribution substrate on the first redistribution substrate, the second redistribution substrate comprising a second insulating layer and a second redistribution pattern;
a first mold layer interposed between the first redistribution substrate and the second redistribution substrate to cover the lower semiconductor chip and the conductive structure;
a first heat-dissipation pattern interposed between the lower semiconductor chip and the second insulating layer; and
a heat-dissipation pad on the conductive structure,
wherein a top surface of the first heat-dissipation pattern is located at a level higher than a top surface of the conductive structure.

2. The semiconductor package of claim 1,
wherein the top surface of the first heat-dissipation pattern is located at the same level as a top surface of the heat-dissipation pad, and
wherein a bottom surface of the first heat-dissipation pattern is located at a level lower than a bottom surface of the heat-dissipation pad.

3. The semiconductor package of claim 1, further comprising a first protection pattern interposed between a lower side surface of the first heat-dissipation pattern and the first mold layer and between a bottom surface of the first heat-dissipation pattern and the lower semiconductor chip.

4. The semiconductor package of claim 3,
wherein the first protection pattern is extended into the second insulating layer, and
wherein the topmost surface of the first protection pattern is located at a level higher than a top surface of the first mold layer.

5. The semiconductor package of claim 3, wherein the topmost surface of the first protection pattern is coplanar with a top surface of the first mold layer.

6. The semiconductor package of claim 1, further comprising:
a pad protection pattern interposed between the conductive structure and the heat-dissipation pad,
wherein the pad protection pattern is provided to expose top and side surfaces of the heat-dissipation pad.

7. The semiconductor package of claim 1, further comprising:
an upper semiconductor chip mounted on the second redistribution substrate; and
a second mold layer provided on the second redistribution substrate to cover the upper semiconductor chip,
wherein the first redistribution pattern comprises a first seed pattern and a first conductive pattern on the first seed pattern.

8. The semiconductor package of claim 1, wherein a width of a bottom surface of the heat-dissipation pad is larger than a width of the conductive structure.

9. The semiconductor package of claim 1,
wherein a first portion of the first heat-dissipation pattern is disposed in the second insulating layer,
wherein a second portion of the first heat-dissipation pattern is disposed in the first mold layer, and
wherein the heat-dissipation pad is disposed in the second insulating layer.

10. The semiconductor package of claim 1, further comprising:
a first protection pattern on the lower semiconductor chip,
wherein the first mold layer has a trench exposing a portion of a top surface of the lower semiconductor chip,
wherein the first protection pattern is provided to fill a portion of the trench, and
wherein the first heat-dissipation pattern is provided to fill a remaining portion of the trench.

11. The semiconductor package of claim 1, further comprising:
a second heat-dissipation pattern disposed between the lower semiconductor chip and the second redistribution pattern and horizontally spaced apart from the first heat-dissipation pattern; and
a second protection pattern interposed between a lower side surface of the second heat-dissipation pattern and the first mold layer and between a bottom surface of the second heat-dissipation pattern and the lower semiconductor chip.

12. A semiconductor package, comprising:
a first redistribution substrate;
a lower semiconductor chip mounted on the first redistribution substrate;
a conductive structure disposed on the first redistribution substrate and horizontally spaced apart from the lower semiconductor chip;
a second redistribution substrate on the first redistribution substrate;
a heat-dissipation pattern on the lower semiconductor chip;
a protection pattern interposed between the lower semiconductor chip and the heat-dissipation pattern and provided to expose a top surface of the heat-dissipation pattern; and
a heat-dissipation pad on the conductive structure.

13. The semiconductor package of claim 12, wherein the heat-dissipation pattern and the protection pattern comprise different materials from each other.

14. The semiconductor package of claim 12, wherein a thickness of the heat-dissipation pattern is larger than a thickness of the heat-dissipation pad.

15. The semiconductor package of claim 12, further comprising:
a pad protection pattern interposed between the conductive structure and the heat-dissipation pad,
wherein the topmost surface of the protection pattern is located at a level lower than a top surface of the pad protection pattern.

16. The semiconductor package of claim 12, wherein a difference between a width of a bottom surface of the heat-dissipation pad and a width of the conductive structure ranges from 2 μm to 30 μm.

17. The semiconductor package of claim 12, further comprising:
an upper semiconductor chip mounted on the second redistribution substrate;
a second mold layer provided on the second redistribution substrate to cover the upper semiconductor chip; and
an outer terminal on a bottom surface of the first redistribution substrate.

18. A semiconductor package, comprising:
a first redistribution substrate including a first insulating layer and a first redistribution pattern;
a first lower semiconductor chip mounted on the first redistribution substrate;
a conductive structure disposed on the first redistribution substrate and horizontally spaced apart from the first lower semiconductor chip;
a first mold layer provided on the first redistribution substrate to cover the first lower semiconductor chip and the conductive structure;
a second redistribution substrate on the first redistribution substrate, the second redistribution substrate comprising a second insulating layer and a second redistribution pattern;
a first heat-dissipation pattern interposed between the first lower semiconductor chip and the second insulating layer;
a first protection pattern interposed between the first lower semiconductor chip and the first heat-dissipation pattern and provided to expose a top surface of the first heat-dissipation pattern;
a heat-dissipation pad on the conductive structure;
a pad protection pattern interposed between the conductive structure and the heat-dissipation pad; and
a first upper semiconductor chip mounted on the second redistribution substrate.

19. The semiconductor package of claim 18, further comprising:
a second lower semiconductor chip mounted on the first redistribution substrate and horizontally spaced apart from the first lower semiconductor chip;
second heat-dissipation patterns interposed between the second lower semiconductor chip and the second insulating layer; and
second protection patterns respectively interposed between the second lower semiconductor chip and the second heat-dissipation patterns.

20. The semiconductor package of claim 18, further comprising:
a second upper semiconductor chip mounted on the second redistribution substrate and horizontally spaced apart from the first upper semiconductor chip; and
a second mold layer provided on the second redistribution substrate to cover the first upper semiconductor chip and the second upper semiconductor chip.
